(19) United States
(12) Patent Application Publication
(10) Pub. No.: US 2025/0015211 A1
(43) Pub. Date: Jan. 9, 2025

(54) PHOTODETECTOR

(71) Applicants: WUHAN OPTICAL VALLEY INFORMATION OPTOELECTRONICS INNOVATION CENTER CO., LTD., Wuhan, Hubei (CN); WUHAN RESEARCH INSTITUTE OF POSTS&TELECOMMUNICATIONS CO., LTD., Wuhan, Hubei (CN)

(72) Inventors: Daigao CHEN, Wuhan (CN); Xi XIAO, Wuhan (CN); Min LIU, Wuhan (CN); Peiqi ZHOU, Wuhan (CN)

(21) Appl. No.: 18/699,945

(22) PCT Filed: Feb. 9, 2022
(86) PCT No.: PCT/CN2022/075716

§ 371 Date: Apr. 10, 2024

(30) Foreign Application Priority Data
Oct. 18, 2021 (CN) 202111210578.6

(51) Int. Cl. H01L 31/0232; H01L 31/105

(52) U.S. Cl. CPC H01L 31/02327; H01L 31/105

(57) ABSTRACT

Embodiments of the present disclosure provide a photodetector, comprising a waveguide structure, a light limiting structure, and an absorption structure. The waveguide structure extends into the light limiting structure, and a first edge where a first side wall of the waveguide structure is located is tangent to a second edge where a second side wall of the light limiting structure is located. The waveguide structure is used for introducing incident light into the light limiting structure in a direction tangent to the first edge. The introduced light is limited in the light limiting structure for annular transmission by means of total reflection of a side wall of the light limiting structure, and the introduced light is coupled into the absorption structure by means of the light limiting structure. The absorption structure is located on the light limiting structure. The coupled light is limited in the absorption structure in the horizontal direction for annular transmission by means of total reflection of a side wall of the absorption structure, and the coupled light is converted into electrons and holes.

### CROSS-REFERENCE TO RELATED APPLICATIONS

The application is based on and claims priority to Chinese Patent Application No. 202111210578.6 filed on Oct. 18, 2021 and entitled “Photodetector”, the entire contents of which are incorporated herein by reference in its entirety.

### TECHNICAL FIELD

The disclosure relates to the field of semiconductor technology, and in particular to a photodetector.

### BACKGROUND

Borrowing ideas from the development route of large-scale integrated circuits, research is being carried out at home and abroad to integrate active devices (e.g., modulators, photodetectors, or the like) and optical waveguide devices (e.g., beamsplitters, couplers, or the like) onto a single substrate, in order to realize photonic chips that have advantages similar to those of large-scale integrated circuits. Photonic chips have characteristics of low cost, small size, low power consumption, flexible scaling and high reliability. Currently, silicon-based photonic chips are considered by the industry as the most promising photonic chips. Adoption of silicon-based photonic chips may combine microelectronics and optoelectronics, give full play to the advantages of silicon-based microelectronics, such as advanced and mature process technology, a high degree of integration, low cost, or the like, and have broad market prospects.

Silicon-based photonic chips have advantages of compatibility with standard semiconductor processes, low cost and high integration, and are gradually widely adopted by the industry. Silicon-based photonic chips generally adopt optical waveguides formed by Silicon On Insulator (SOI) materials. An optical waveguide is formed by a Si core layer and a SiO₂ cladding. The large difference of refractivity between the core layer and the cladding has a strong limiting effect on the light field, which may realize a waveguide bending radius of micrometer scale, thereby providing a realization basis for miniaturization and high-density integration of silicon-based photonic chips.

In the field of optical communication, a germanium-silicon waveguide-type photodetector is often used as the receiving end of a silicon-based photonic chip. The germanium-silicon waveguide-type photodetector is a device that converts high-speed optical signals into current signals, and is a key device of the silicon-based photonic chip. The germanium-silicon waveguide-type photodetector mainly generates photocurrent by light absorption of the germanium material. In the related art, it is necessary to further improve the responsivity of the photodetector while taking into account the bandwidth of the photodetector.

### SUMMARY

In view of the above, embodiments of the disclosure are expected to provide a photodetector.

In order to achieve the above purpose, the technical solution of the disclosure is implemented as follows.

The photodetector includes a waveguide structure, a light trapping structure and an absorption structure.

The waveguide structure extends into the light trapping structure. A first side, on which a first sidewall of the waveguide structure is positioned, is tangent to a second side, on which a second sidewall of the light trapping structure is positioned. The waveguide structure is configured to import incident light into the light trapping structure in a direction tangent to the first side. The imported light is confined to travel annularly within the light trapping structure by total internal reflection of sidewalls of the light trapping structure, and the imported light is coupled into the absorption structure through the light trapping structure.

The absorption structure is positioned on the light trapping structure. The coupled light is confined to travel annularly within the absorption structure by total internal reflection of sidewalls of the absorption structure, and the coupled light is converted into electrons and holes.

In the above solution, the shape of the projection of the waveguide structure on a preset plane includes an elongated shape.

The shape of the projection of the light trapping structure on the preset plane includes an enclosed shape formed by at least one straight line and/or at least one curve. The angle formed by the second side, on which the second sidewall of the light trapping structure is positioned, and a third side, on which a third sidewall of the light trapping structure is positioned, is an obtuse angle.

Here, the preset plane is perpendicular to the direction of the thickness of the light trapping structure, and the third sidewall is a sidewall where the incident light is reflected for the first time after the incident light enters the light trapping structure.

In the above solution, the shape of the projection of the light trapping structure on the preset plane includes one of:
a circle; an enclosed shape formed by connecting multiple curves; an enclosed shape formed by connecting multiple straight lines and multiple curves; or a polygon.

In the above solution, the polygon includes a regular polygon and has a number of sides greater than or equal to 6.

In the above solution, the projection of the light trapping structure on the preset plane covers the projection of the absorption structure on the preset plane.

In the above solution, the photodetector further includes a slab structure, a first doped structure, a first doped region, a second doped region, a first electrode and a second electrode.

The slab structure surrounds the waveguide structure and the light trapping structure; and the thickness of the waveguide structure is greater than the thickness of the slab structure.

The first doped structure is positioned in the slab structure and surrounds the light trapping structure.

The first doped region is positioned on the surface of the first doped structure and a region with a certain depth downward from the surface of the first doped structure.

The second doped region is positioned on the surface of the absorption structure and a region with a certain depth downward from the surface of the absorption structure. The first electrode is positioned on the first doped region, and the first electrode is configured to collect electrons or holes flowing sequentially along the absorption structure, the light trapping structure, the first doped structure, and the first doped region.

The second electrode is positioned on the second doped region, and the second electrode is configured to collect electrons or holes flowing sequentially along the absorption structure and the second doped region.

In the above solution, the thickness of the waveguide structure is the same as the thickness of the light trapping structure, and the thickness of the waveguide structure is greater than the thickness of the slab structure.

In the above solution, the photodetector further includes a second doped structure and a recessed structure.

The second doped structure is positioned between the slab structure and the light trapping structure. The thickness of the second doped structure is less than the thickness of the light trapping structure, and the thickness of the second doped structure is less than the thickness of the first doped structure. The thickness of the waveguide structure is the same as the thickness of the light trapping structure.

The recessed structure is positioned between the slab structure and the waveguide structure. The thickness of the recessed structure is less than the thickness of the slab structure, and the thickness of the recessed structure is less than the thickness of the waveguide structure.

The first electrode is further configured to collect electrons or holes flowing sequentially along the absorption structure, the light trapping structure, the second doped structure, the first doped structure, and the first doped region.

In the above solution, the doping concentration of the first doped structure is greater than or equal to the doping concentration of the second doped structure; and the doping concentration of the second doped structure is greater than or equal to the doping concentration of the light trapping structure.

The photodetector provided by the embodiments of the disclosure includes a waveguide structure, a light trapping structure and an absorption structure. The waveguide structure extends into the light trapping structure. A first side, on which a first sidewall of the waveguide structure is positioned, is tangent to a second side, on which a second sidewall of the light trapping structure is positioned. The waveguide structure is configured to import incident light into the light trapping structure in a direction tangent to the first side. The imported light is confined to travel annularly within the light trapping structure by total internal reflection of sidewalls of the light trapping structure, and the imported light is coupled into the absorption structure through the light trapping structure. The absorption structure is positioned on the light trapping structure. The coupled light is confined to travel annularly within the absorption structure by total internal reflection of sidewalls of the absorption structure, and the coupled light is converted into electrons and holes. With the photodetector provided by the embodiments of the disclosure, the incident light enters the light trapping structure through the waveguide structure along the direction tangent to the second side on which the second sidewall of the light trapping structure is positioned, and the incident light is absorbed by coupling the incident light to the absorption structure through the light trapping structure. Furthermore, the light trapping structure and the absorption structure adopt structures such as circular, optimally deformed circular-like or polygonal structures, which may confine light to stably travelling within an enclosed structure and reduce the excitation to high-order modes of the incident light during the propagation process in the light trapping structure and the absorption structure. In this way, the leakage of light may be reduced, and thereby the responsivity of the photodetector is improved. In addition, in the light trapping structure, the incident light can not escape from the light trapping structure in a first direction due to the total internal reflection effect of the sidewalls, and finally all of the incident light is coupled into the absorption structure along a second direction. In the absorption structure, the incident light will also be confined within the absorption structure due to the total internal reflection effect of the sidewalls. In other words, the incident light propagates annularly in the light trapping structure and the absorption structure until the incident light is completely absorbed. The annular propagation may reduce the size requirements of the light trapping structure and the absorption structure, that is, the annular propagation may reduce the size requirements of the photodetector, and a smaller size of the photodetector may bring smaller parasitic parameters of the photodetector, thereby enabling the photodetector to have a higher bandwidth. Therefore, the photodetector provided by the embodiments of the disclosure may balance a high bandwidth and a high responsivity simultaneously.

### BRIEF DESCRIPTION OF THE DRAWINGS

FIG. 1 is a first schematic top view of a photodetector provided by an embodiment of the disclosure.

FIG. 2 is a second schematic top view of a photodetector provided by an embodiment of the disclosure.

FIG. 3 is a third schematic top view of a photodetector provided by an embodiment of the disclosure.

FIG. 4 is a cross-sectional diagram of FIGS. 1, 2 and 3 along the A1-A1 direction.

FIG. 5 is a cross-sectional diagram of FIGS. 1, 2 and 3 along the B1-B1 direction.

FIG. 6 is a fourth schematic top view of a photodetector provided by an embodiment of the disclosure.

FIG. 7 is a fifth schematic top view of a photodetector provided by an embodiment of the disclosure.

FIG. 8 is a sixth schematic top view of a photodetector provided by an embodiment of the disclosure.

FIG. 9 is a cross-sectional diagram of FIGS. 5, 6 and 7 along the A2-A2 direction.

FIG. 10 is a cross-sectional diagram of FIGS. 5, 6 and 7 along the B2-B2 direction.

### DETAILED DESCRIPTION

The technical solutions of the disclosure are further illustrated in detail in combination with the drawings of the specification and specific embodiments.

In the description of the disclosure, it is to be understood that the terms “length”, “width”, “depth”, “upper”, “lower”, “outer”, or the like, indicate orientations or positional relationships based on those illustrated in the drawings, and are only intended to facilitate and simplify the description of the disclosure, instead of indicating or implying that the apparatus or element referred to must have a particular orientation, or be constructed and operated in a particular orientation, and thus can not be understood as a limitation on the disclosure.

In the embodiments of the disclosure, the term “substrate” refers to a material on which a subsequent material layer is added. The substrate itself may be patterned. The material added on the top of the substrate may be patterned or may be remained unpatterned. In addition, the substrate may include a variety of semiconductor materials, such as silicon, germanium, gallium arsenide, indium phosphide, or the like. Alternatively, the substrate may be made of a non-conductive material, such as glass, plastic, or a sapphire wafer.

In the embodiments of the disclosure, the term “layer” refers to a material part including a region with a thickness. A layer may extend on the entirety of an upper structure or a lower structure, or may have a scope that is smaller than the scope of the upper structure or the lower structure. In addition, a layer may be a region of a homogeneous or non-homogeneous continuous structure with a thickness less than the thickness of the continuous structure. For example, a layer may be positioned between the top surface and the bottom surface of the continuous structure, or a layer may be positioned between any pair of horizontal planes at the top surface and bottom surface of the continuous structure. A layer may extend horizontally, vertically, and/or along an inclined surface. A layer may include multiple sub-layers. For example, an interconnection layer may include one or more conductors and contact sub-layers (in which interconnection wires and/or via hole contacts are formed), and one or more dielectric sub-layers.

In the embodiments of the disclosure, the terms “first”, “second” or the like are used to distinguish similar objects, and need not to be used to describe a particular order or sequence.

It is to be noted that the technical solutions disclosed in the embodiments of the disclosure may be arbitrarily combined without conflict.

A germanium-silicon waveguide-type photodetector generally adopts a square structure, in which light is incident from one end of the light trapping structure, exits from the corresponding other end, and experiences one-way absorption. On one hand, in order to improve the responsivity of the photodetector, it is necessary to absorb as much light as possible, and thereby it is necessary to increase the size of the photodetector to obtain a higher responsivity. On the other hand, when the size of the photodetector is increased, the parasitic parameters of the photodetector will be increased, which will result in a decrease in the photoelectric bandwidth of the photodetector. It can be seen from the above that, currently, there is a mutual restrictive relationship between the responsivity and the photoelectric bandwidth of the photodetector.

Based on this, the embodiments of the disclosure intend to provide a photodetector that balances a high bandwidth and a high responsivity. In the embodiments of the disclosure, the incident light enters the light trapping structure through the waveguide structure along the direction tangent to the second side on which the second sidewall of the light trapping structure is positioned, and the incident light is absorbed by coupling the incident light to the absorption structure along a second direction through the light trapping structure. Furthermore, the light trapping structure and the absorption structure adopt structures such as circular, optimally deformed circular-like or polygonal structures, which may confine light to stably travelling within an enclosed structure and reduce the excitation to high-order modes of the incident light during the propagation process in the light trapping structure. In this way, the leakage of light may be reduced, and thereby the responsivity of the photodetector is improved. In addition, in the light trapping structure, the incident light can not escape from the light trapping structure in a first direction due to the total internal reflection effect of the sidewalls, and finally all of the incident light is coupled into the absorption structure along the second direction. In the absorption structure, the incident light will also be confined within the absorption structure due to the total internal reflection effect of the sidewalls. In other words, the incident light propagates annularly in the light trapping structure and the absorption structure. The annular propagation may reduce the size requirements of the light trapping structure and the absorption structure, that is, the annular propagation may reduce the size requirements of the photodetector, and a smaller size of the photodetector may bring smaller parasitic parameters of the photodetector, thereby enabling the photodetector to have a higher bandwidth. Therefore, the photodetector provided by the embodiments of the disclosure may balance a high bandwidth and a high responsivity simultaneously.

An embodiment of the disclosure provides a photodetector that includes a waveguide structure, a light trapping structure and an absorption structure.

The waveguide structure extends into the light trapping structure. A first side, on which a first sidewall of the waveguide structure is positioned, is tangent to a second side, on which a second sidewall of the light trapping structure is positioned. The waveguide structure is configured to import incident light into the light trapping structure in a direction tangent to the first side. The imported light is confined to travel annularly within the light trapping structure by total internal reflection of sidewalls of the light trapping structure, and the imported light is coupled into the absorption structure through the light trapping structure. The absorption structure is positioned on the light trapping structure. The coupled light is confined to travel annularly within the absorption structure by total internal reflection of sidewalls of the absorption structure, and the coupled light is converted into electrons and holes.

Here, in a practical application, the waveguide structure is configured to propagate incident light, and the incident light enters the light trapping structure through the waveguide structure. The waveguide structure may be a silicon waveguide and formed by a silicon (Si) core layer and a silicon dioxide (SiO₂) cladding.

In a practical application, the light trapping structure is configured to confine the imported light to travel annularly within a coupling structure in a first direction by total internal reflection of the sidewalls, and further, to couple all of the imported light into the absorption structure in a second direction perpendicular to the first direction. The light trapping structure may include lightly doped silicon. It is to be noted that in the embodiments of the disclosure, the light trapping structure coupling all of the imported light into the absorption structure in the second direction perpendicular to the first direction may be understood as follows. From the perspective of theoretical design, the light entering the light trapping structure may propagate in an annular path by the total internal reflection of the sidewalls of the light trapping structure, and thereby 100% enter the absorption structure. However, in a practical application, due to the process and other factors, such as the inevitable presence of a very small amount of scattering on the reflecting surface, or absorption of the doped region, the light entering the light trapping structure can not 100% completely enter the absorption structure. The above caused light loss is not included in the above meaning of “all”.

It is to be noted that in case that the light trapping structure and the absorption structure are set to be stacked, the first direction is perpendicular to the stacking direction, and the second direction is the stacking direction. It is to be understood that in case that the light trapping structure and the absorption structure are set to be stacked vertically, the first direction is the horizontal direction, and the second direction is the vertical direction.

Here, the waveguide structure may include multiple sidewalls, and at least one side, on which one of the sidewalls is positioned, is a straight side. Specifically, a first side, on which a first sidewall of the waveguide structure is positioned, is a straight side.

In an embodiment, the light trapping structure may include multiple sidewalls, and an side, on which one of the sidewalls is positioned, is a curve. The first side, on which the first sidewall of the waveguide structure is positioned, is tangent to the curve.

In an embodiment, the light trapping structure may include multiple sidewalls, and an side, on which one of the sidewalls is positioned, is a straight line. Specifically, a second side, on which a second sidewall of the light trapping structure is positioned, is a straight line, and the first side, on which the first sidewall of the waveguide structure is positioned, is tangent to the straight line.

In an embodiment, the shape of the projection of the waveguide structure on a preset plane includes an elongated shape. The shape of the projection of the light trapping structure on the preset plane includes an enclosed shape formed by at least one straight line and/or at least one curve. The angle formed by the second side, on which the second sidewall of the light trapping structure is positioned, and a third side, on which a third sidewall of the light trapping structure is positioned, is an obtuse angle. Here, the preset plane is perpendicular to the direction of the thickness of the light trapping structure, and the third sidewall is a sidewall where the incident light is reflected for the first time after the incident light enters the light trapping structure. In a practical application, in case that the projection of one of the sidewalls of the light trapping structure on the preset plane is a curve, the first side, on which the first sidewall of the waveguide structure is positioned, is tangent to the curve. In case that the projection one of the sidewalls of the light trapping structure on the preset plane is a straight line, the first side, on which the first sidewall of the waveguide structure is positioned, is tangent to the straight line.

It is to be understood that the incident light may be imported into the light trapping structure through the waveguide structure in a direction tangent to the sidewall of the waveguide structure, and the mutation of the incident light during the propagation process in the waveguide structure and the light trapping structure is reduced. In this way, the high-order modes of the light excited during the propagation process are reduced, the stability of the incident light during the propagation process is improved, the leakage of light is reduced, and thereby the responsivity of the photodetector is improved.

In an embodiment, the sides, on which the sidewalls of the light trapping structure are positioned, include at least one arc, and the first side, on which the first sidewall of the waveguide structure is positioned, is tangent to one of the at least one arc.

In an embodiment, the sides, on which the sidewalls of the light trapping structure are positioned, include at least one straight line and at least one curve, and the first side, on which the first sidewall of the waveguide structure is positioned, is tangent to the at least one straight line or the curve.

In an embodiment, the sides, on which the sidewalls of the light trapping structure are positioned, include multiple straight lines, and the first side, on which the first sidewall of the waveguide structure is positioned, is tangent to one of the multiple straight lines. In a practical application, the angle formed by the second side, on which the second sidewall of the light trapping structure is positioned, and the third side, on which the third sidewall of the light trapping structure is positioned, is an obtuse angle. Here, in case that the sides, on which the sidewalls of the light trapping structure are positioned, include multiple straight lines, the angle formed by the second side, on which the second sidewall of the light trapping structure is positioned, and the third side, on which the third sidewall of the light trapping structure is positioned, is an obtuse angle. In case that the sides, on which the sidewalls of the light trapping structure are positioned, include at least one curve, either the second side, on which the second sidewall of the light trapping structure is positioned, or the third side, on which the third sidewall of the light trapping structure is positioned, may be regarded as an side on which the curve is positioned. It is to be noted that a curve may be regarded as a figure consisting of countless straight lines. It is to be understood that the reflection angle where the incident light is reflected for the first time after the incident light enters the light trapping structure is not equal to 0 degree. In other words, after entering the light trapping structure, the incident light will not be reflected back directly from the entrance of the incident light, thereby avoiding the leakage of light from the entrance of the incident light.

In a practical application, the absorption structure is positioned on the light trapping structure, and the absorption structure is configured to convert the coupled light into electrons and holes. The absorption structure may include a germanium absorption region.

In the above embodiment, the incident light enters the light trapping structure through the waveguide structure along the direction tangent to the second side on which the second sidewall of the light trapping structure is positioned, and the incident light is absorbed by coupling the incident light to the absorption structure along a second direction through the light trapping structure. Furthermore, the light trapping structure and the absorption structure adopt structures such as circular, optimally deformed circular-like or polygonal structures, which may confine light to stably travelling within an enclosed structure and reduce the excitation to high-order modes of the incident light during the propagation process in the light trapping structure. In this way, the leakage of light may be reduced, and thereby the responsivity of the photodetector is improved. In addition, in the light trapping structure, the incident light can not escape from the light trapping structure in a first direction due to the total internal reflection effect of the sidewalls, and finally all of the incident light is coupled into the absorption structure along the second direction. In the absorption structure, the incident light will also be confined within the absorption structure due to the total internal reflection effect of the sidewalls. In other words, the incident light propagates annularly in the light trapping structure and the absorption structure. The annular propagation may reduce the size requirements of the light trapping structure and the absorption structure, that is, the annular propagation may reduce the size requirements of the photodetector, and a smaller size of the photodetector may bring smaller parasitic parameters of the photodetector, thereby enabling the photodetector to have a higher bandwidth. Therefore, the photodetector provided by the embodiments of the disclosure may balance a high bandwidth and a high responsivity simultaneously.

It is to be noted that the solutions provided by the embodiments of the disclosure apply to germanium-silicon waveguide-type photodetectors, and in addition, may also apply to photodetectors of the semiconductor material system, such as indium gallium arsenic/indium phosphorus (InGaAs/InP) series materials, aluminum gallium arsenic/gallium aluminum (AlGaAs/GaAl) series materials, gallium nitride (GaN) series materials, silicon carbide (SiC), or the like. Here, the photodetector includes the waveguide-type photodetector, and the waveguide-type photodetector includes an incident waveguide. The incident waveguide is configured to propagate incident light, and the incident light enters the light trapping structure through the incident waveguide and is coupled into the absorption structure. In a practical application, the incident waveguide at least includes a waveguide structure.

The specific structure of the incident waveguide is not limited in the embodiments of the disclosure. Specifically, the photodetector in the embodiments of the disclosure may include a rib waveguide or a waveguide of other shape. In the following, the solution provided by the embodiments of the disclosure is exemplarily described only with a germanium-silicon waveguide-type photodetector that has a rib waveguide.

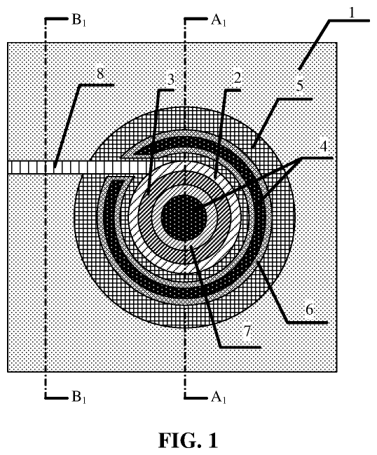

As illustrated in FIGS. 1 to 5, the photodetector includes a slab structure 1, a waveguide structure 8, a light trapping structure 2, an absorption structure 3, a first electrode 4-1, a second electrode 4-2, a first doped structure 5, a first doped region 6, and a second doped region 7.

Here, the slab structure 1 and the waveguide structure 8 form a rib waveguide, and the rib waveguide is a silicon waveguide for propagating incident light. The light trapping structure 2 is configured to receive the incident light propagated by the rib waveguide, and to confine the imported light to travel annularly within a coupling structure in a first direction by total internal reflection of the sidewalls, and further, to couple the imported light into the absorption structure 3 through the light trapping structure in a second direction perpendicular to the first direction. The absorption structure 3 is positioned on the light trapping structure 2, and is configured to confine the coupled light to travel annularly within the absorption structure in the first direction by the total internal reflection of the sidewalls, and to convert the coupled light into electrons and holes. The waveguide structure 8 extends into the light trapping structure 2. A first side, on which a first sidewall of the waveguide structure 8 is positioned, is tangent to or overlaps with a second side, on which a second sidewall of the light trapping structure 2 is positioned. The waveguide structure 8 is configured to import the incident light into the light trapping structure 2 in a direction tangent to the first side.

It is to be noted that the light trapping structure 2 is configured to receive the incident light propagated by the rib waveguide, and to confine the imported light to travel annularly within the coupling structure in the first direction by the total internal reflection of the sidewalls, and further, to couple the imported light into the absorption structure 3 through the light trapping structure in the second direction perpendicular to the first direction. It is to be understood that the incident light is confined to travel annularly within the coupling structure in the first direction by the total internal reflection effect of the sidewalls of the light trapping structure 2, while all of the incident light is coupled into the absorption structure 3 through the light trapping structure in the second direction perpendicular to the first direction, and then all of the incident light is absorbed by the absorption structure 3.

Next, continuously refer to FIGS. 1 to 5. The first doped structure 5 is positioned in the slab structure 1 and surrounds the light trapping structure 2. The first doped region 6 is positioned on the surface of the first doped structure 5 and a region with a certain depth downward from the surface of the first doped structure 5. The second doped region 7 is positioned on the surface of the absorption structure 3 and a region with a certain depth downward from the surface of the absorption structure 3. The first electrode 4-1 is positioned on the first doped region 6, and the first electrode 4-1 is configured to collect electrons or holes flowing sequentially along the absorption structure 3, the light trapping structure 2, the first doped structure 5, and the first doped region 6. The second electrode 4-2 is positioned on the second doped region 7, and the second electrode 4-2 is configured to collect electrons or holes flowing sequentially along the absorption structure 3 and the second doped region 7.

Here, the light trapping structure 2 and the first doped structure 5 include a lightly doped silicon region respectively, the absorption structure 3 includes a germanium absorption region, the first doped region 6 includes a heavily doped silicon region, and the second doped region 7 includes a germanium doped region. The first electrode 4-1 is positioned on the heavily doped silicon region, and the second electrode 4-2 is positioned on the germanium doped region. Electrons and holes are generated by the incident light after the incident light is absorbed by the germanium absorption region. The electrons and holes enter the lightly doped silicon region and the germanium doped region respectively under the action of an electric field. The electrons or holes entering the lightly doped silicon region enter the heavily doped silicon region under the action of the electric field and are then collected by the first electrode 4-1 on the heavily doped silicon region. The holes or electrons entering the germanium doped region are collected by the second electrode 4-2 on the germanium doped region.

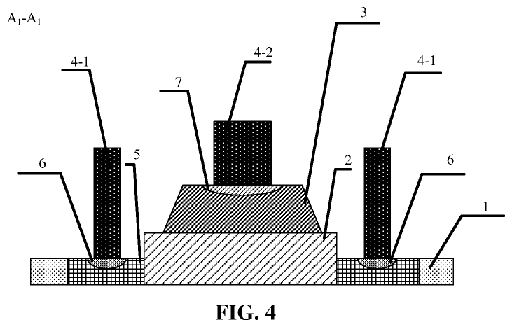

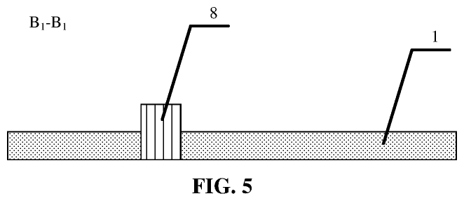

As illustrated in FIGS. 4 and 5, the thickness of the waveguide structure 8 is greater than the thickness of the slab structure 1. The thickness of the waveguide structure 8 is the same as the thickness of the light trapping structure 2. In this way, reflection and refraction of light at the entrance where the light enters the light trapping structure 2 from the waveguide structure 8 may be reduced, thereby reducing the leakage of light.

In an embodiment, the doping concentration of the lightly doped silicon region in the first doped structure 5 is greater than the concentration of the lightly doped silicon region in the light trapping structure 2.

In an embodiment, the doping concentration of the lightly doped silicon region in the first doped structure 5 is equal to the concentration of the lightly doped silicon region in the light trapping structure 2. In some embodiments, the shape of the projection of the light trapping structure on the preset plane includes one of:
a circle;
an enclosed shape formed by connecting multiple curves;
an enclosed shape formed by connecting multiple straight lines and multiple curves; or
a polygon.

In an embodiment, referring to FIG. 1, the shape of the projection of the light trapping structure 2 on the preset plane is a circle. The waveguide structure 8 extends into the light trapping structure 2, and the first side, on which the first sidewall of the waveguide structure 8 is positioned, is tangent to the round side of the light trapping structure 2. The incident light propagates annularly in the circular light trapping structure 2, and thus the size of the photodetector may be reduced, and thereby the parasitic parameters of the photodetector are reduced, which enables the photodetector to have a higher bandwidth. Here, the preset plane is perpendicular to the direction of the thickness of the light trapping structure, and the plane, on which the slab structure 1 is positioned, is parallel to the preset plane.

In an embodiment, the shape of the projection of the light trapping structure 2 on the preset plane is an enclosed shape formed by connecting multiple curves. The waveguide structure 8 extends into the light trapping structure 2, and the first side, on which the first sidewall of the waveguide structure 8 is positioned, is tangent to one of the multiple curves. The one of the multiple curves has a radius of curvature approaching infinity at the point of tangency. Each of the multiple curves includes a first sub-curve and a second sub-curve that are identical. The radius of curvature of the first sub-curve approaches infinity at a first endpoint, and the radius of curvature of the first sub-curve gradually decreases from the first endpoint to a second endpoint where the first sub-curve is connected to the second sub-curve.

In an embodiment, the shape of the projection of the light trapping structure 2 on the preset plane is an enclosed shape formed by connecting four identical curves. The curves bend at an angle of 90 degrees, and each of the four curves is divided into two identical sub-curves by a 45-degree equidistant line. Any one of the sub-curves has a radius of curvature which gradually decreases as the sub-curve approaches towards the 45-degree equidistant line from the endpoint of the sub-curve remote from the 45-degree equidistant line, and the radius of curvature decreases to a certain value when the sub-curve reaches the 45-degree equidistant line. The radius of curvature of the shape of the projection of the light trapping structure 2 on the preset plane varies gradually, thereby avoiding the generation of more high-order modes when light propagates in the light trapping structure 2, which is conducive to reducing the leakage of light.

In an embodiment, the shape of the projection of the light trapping structure 2 on the preset plane is an enclosed shape formed by connecting four identical curves. The curves bend at an angle of 90 degrees, and each of the four curves has a 45-degree equidistant line. Each of the four curves is divided into a third sub-curve, a fourth sub-curve and a fifth sub-curve sequentially from a first endpoint to a second endpoint. The third sub-curve and the fifth sub-curve have radii of curvature which gradually decrease as they approach towards the 45-degree equidistant line from the first endpoint and the second endpoint respectively, and the third sub-curve and the fifth sub-curve are connected by the fourth sub-curve when they do not reach the 45-degree equidistant line. The radii of curvature at the two endpoints of the fourth sub-curve are equal to the radius of curvature of the third sub-curve at the endpoint close to the 45-degree equidistant line and the radius of curvature of the fifth sub-curve at the endpoint close to the 45-degree equidistant line, respectively. The radius of curvature of the shape of the projection of the light trapping structure 2 on the preset plane varies uniformly, thereby avoiding the generation of more high-order modes when light propagates in the light trapping structure 2, which is conducive to reducing the leakage of light.

In an embodiment, the shape of the projection of the light trapping structure 2 on the preset plane is an enclosed shape formed by connecting multiple straight lines and multiple curves. The waveguide structure 8 extends into the light trapping structure 2, and the first side, on which the first sidewall of the waveguide structure 8 is positioned, overlaps with one of the straight lines of the enclosed shape.

In an embodiment, the shape of the projection of the light trapping structure 2 on the preset plane is an enclosed shape formed by alternately connecting multiple straight lines and multiple curves. Each of the multiple curves includes a sixth sub-curve and a seventh sub-curve that are identical. The radius of curvature of the sixth sub-curve gradually decreases from a first endpoint where the sixth sub-curve is tangent to the straight line, to a second endpoint where the sixth sub-curve is connected to the seventh sub-curve.

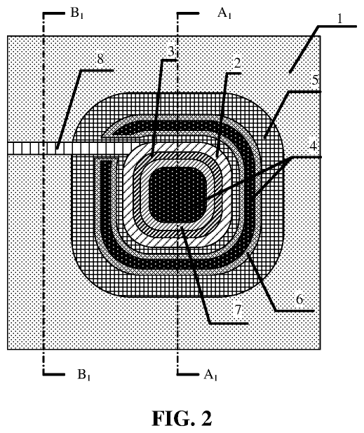

In an embodiment, referring to FIG. 2, the shape of the projection of the light trapping structure 2 on the preset plane is an enclosed shape formed by alternately connecting four identical straight lines and four identical curves. The waveguide structure 8 extends into the light trapping structure 2, and the first side, on which the first sidewall of the waveguide structure 8 is positioned, overlaps with one of the straight lines of the enclosed shape. It is to be understood that the incident light propagates straight at least along one of the straight sides when entering the light trapping structure 2, and subsequently propagates annularly in the light trapping structure 2 formed by the enclosed shape. Therefore, on one hand, the high-order modes of the light excited during the propagation process may be reduced, the leakage of light may be reduced, and the responsivity of the photodetector may be improved. On the other hand, the size of the photodetector may be reduced, thereby reducing the parasitic parameters of the photodetector and enabling the photodetector to have a higher bandwidth.

In an embodiment, the shape of the projection of the light trapping structure 2 on the preset plane is an enclosed shape formed by alternately connecting four identical straight lines and four identical curves. The curves bend at an angle of 90 degrees, and each of the four curves is divided into two identical sub-curves by a 45-degree equidistant line. Any one of the sub-curves has a radius of curvature which gradually decreases as the sub-curve approaches towards the 45-degree equidistant line from the endpoint of the sub-curve remote from the 45-degree equidistant line, and the radius of curvature decreases to a certain value when the sub-curve reaches the 45-degree equidistant line. The radius of curvature of the shape of the projection of the light trapping structure 2 on the preset plane varies gradually, thereby avoiding the generation of more high-order modes when light propagates in the light trapping structure 2, which is conducive to reducing the leakage of light.

In an embodiment, the shape of the projection of the light trapping structure 2 on the preset plane is an enclosed shape formed by alternately connecting four identical straight lines and four identical curves. The curves bend at an angle of 90 degrees, and each of the four curves has a 45-degree equidistant line. Each of the four curves is divided into an eighth sub-curve, a ninth sub-curve and a tenth sub-curve sequentially from a first endpoint to a second endpoint. The eighth sub-curve and the tenth sub-curve have radii of curvature which gradually decrease as they approach towards the 45-degree equidistant line from the first endpoint and the second endpoint respectively, and the eighth sub-curve and the tenth sub-curve are connected by the ninth sub-curve when they do not reach the 45-degree equidistant line. The radii of curvature at the two endpoints of the ninth sub-curve are equal to the radius of curvature of the eighth sub-curve at the endpoint close to the 45-degree equidistant line and the radius of curvature of the tenth sub-curve at the endpoint close to the 45-degree equidistant line, respectively. The radius of curvature of the shape of the projection of the light trapping structure 2 on the preset plane varies uniformly, thereby avoiding the generation of more high-order modes when light propagates in the light trapping structure 2, which is conducive to reducing the leakage of light.

In an embodiment, the shape of the projection of the light trapping structure 2 on the preset plane is a polygon. The waveguide structure 8 extends into the light trapping structure 2, and the first side, on which the first sidewall of the waveguide structure 8 is positioned, overlaps with one of the sides of the polygon. The angle formed by the second side, on which the second sidewall of the light trapping structure 2 is positioned, and a third side, on which a third sidewall of the light trapping structure 2 is positioned, is an obtuse angle. The third sidewall is a sidewall where the incident light is reflected for the first time after the incident light enters the light trapping structure 2. It is to be understood that the reflection angle where the incident light is reflected for the first time after the incident light enters the light trapping structure 2 is not equal to 0 degree. In other words, after entering the light trapping structure 2, the incident light will not be reflected back from the entrance of the incident light, thereby avoiding the leakage of light from the entrance of the incident light.

In an embodiment, the polygon includes a regular polygon and has a number of sides greater than or equal to 6.

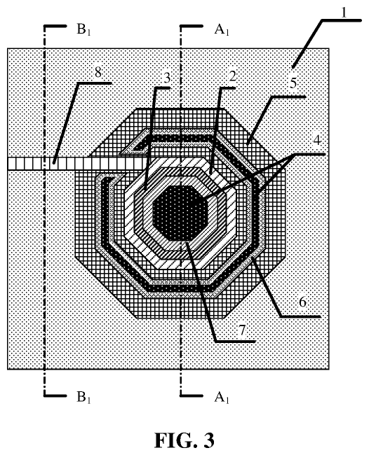

In an embodiment, referring to FIG. 3, the shape of the projection of the light trapping structure 2 on the preset plane is a regular octagon. The waveguide structure 8 extends into the light trapping structure 2, and the first side, on which the first sidewall of the waveguide structure 8 is positioned, is tangent to one of the sides of the regular octagon. The incident light propagates annularly along the regular octagon after entering the light trapping structure 2 from the waveguide structure 8.

In an embodiment, as illustrated in FIGS. 1 to 3, the shape of the projection of the light trapping structure 2 on the preset plane is the same as the shape of the projection of the absorption structure 3 on the preset plane. The incident light propagates annularly in the light trapping structure 2 and the germanium absorption region. Since the sizes of the light trapping structure 2 and the germanium absorption region may be very small and still satisfy the propagation requirements, based on this, the size of the photodetector may also be very small, and thus the parasitic parameters of the photodetector will be very small, such that the germanium-silicon waveguide-type photodetector has a higher bandwidth. Therefore, the germanium-silicon waveguide-type photodetector may balance a high bandwidth and a high responsivity simultaneously, which has obvious advantages. It is to be noted that the shape of the projection of the light trapping structure 2 on the preset plane may be different from the shape of the projection of the absorption structure 3 on the preset plane.

In an embodiment, as illustrated in FIGS. 1 to 3, the projection of the light trapping structure 2 on the preset plane covers the projection of the absorption structure 3 on the preset plane. The area of the light trapping structure 2 is larger than the area of the absorption structure 3, which may better provide a growth platform for the absorption structure 3.

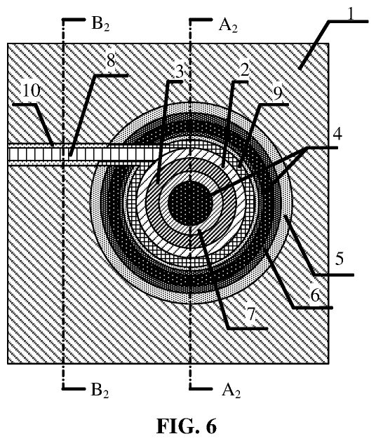

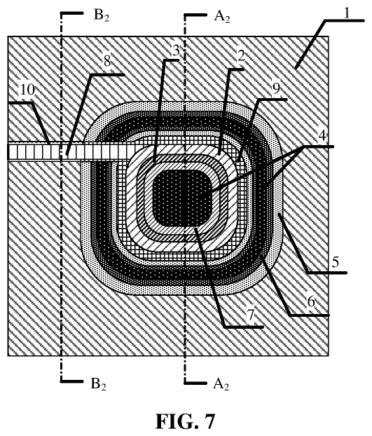

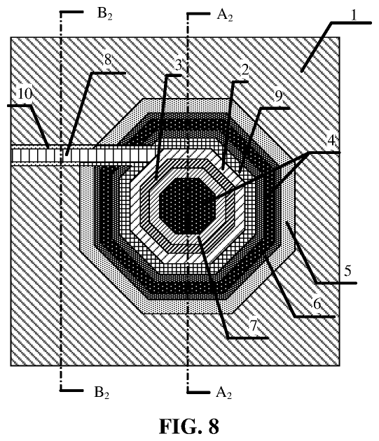

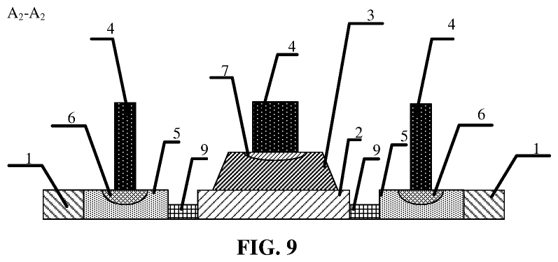

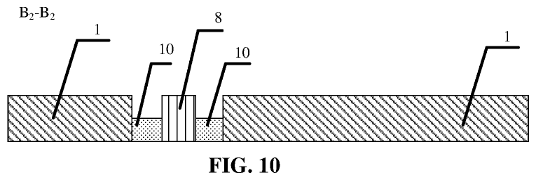

In an embodiment, as illustrated in FIGS. 6 to 10, the photodetector further includes a second doped structure 9, and the rib waveguide further includes a recessed structure 10. The second doped structure 9 is positioned between the slab structure 1 and the light trapping structure 2. The thickness of the second doped structure 9 is less than the thickness of the light trapping structure 2, and the thickness of the second doped structure 9 is less than the thickness of the first doped structure 5. The thickness of the waveguide structure 8 is the same as the thickness of the light trapping structure 2. The recessed structure 10 is positioned between the slab structure 1 and the waveguide structure 8. The thickness of the recessed structure 10 is less than the thickness of the slab structure 1, and the thickness of the recessed structure 10 is less than the thickness of the waveguide structure 8. The first electrode 4-1 is further configured to collect electrons or holes flowing sequentially along the absorption structure 3, the light trapping structure 2, the second doped structure 9, the first doped structure 5, and the first doped region 6.

It is to be understood that in the above embodiment, the second doped structure 9 surrounds the light trapping structure 2 and forms a recessed region between the first doped structure 5 and the light trapping structure 2. The recessed region formed by the second doped structure 9 may reflect a portion of leaked light back to the light trapping structure 2 and then into the absorption structure 3 to be absorbed, which further improves the responsivity of the photodetector.

In an embodiment, the thickness of the second doped structure 9 is the same as the thickness of the recessed structure 10. The doping concentration of the first doped structure 5 is greater than or equal to the doping concentration of the second doped structure 9, and the doping concentration of the second doped structure 9 is greater than or equal to the doping concentration of the light trapping structure 2.

The photodetector provided by the embodiments of the disclosure includes a waveguide structure, a light trapping structure and an absorption structure. The waveguide structure extends into the light trapping structure. A first side, on which a first sidewall of the waveguide structure is positioned, is tangent to a second side, on which a second sidewall of the light trapping structure is positioned. The waveguide structure is configured to import incident light into the light trapping structure in a direction tangent to the first side. The imported light is confined to travel annularly within the light trapping structure by total internal reflection of sidewalls of the light trapping structure, and the imported light is coupled into the absorption structure through the light trapping structure. The absorption structure is positioned on the light trapping structure. The coupled light is confined to travel annularly within the absorption structure in the horizontal direction by total internal reflection of sidewalls of the absorption structure, and the coupled light is converted into electrons and holes. With the photodetector provided by the embodiments of the disclosure, the incident light enters the light trapping structure through the waveguide structure along the direction tangent to the second side on which the second sidewall of the light trapping structure is positioned, and the incident light is absorbed by coupling the incident light to the absorption structure along a second direction through the light trapping structure. Furthermore, the light trapping structure and the absorption structure adopt structures such as circular, optimally deformed circular-like or polygonal structures, which may confine light to stably travelling within an enclosed structure and reduce the excitation to high-order modes of the incident light during the propagation process in the light trapping structure. In this way, the leakage of light may be reduced, and thereby the responsivity of the photodetector is improved. In addition, in the light trapping structure, the incident light can not escape from the light trapping structure in a first direction due to the total internal reflection effect of the sidewalls, and finally all of the incident light is coupled into the absorption structure along the second direction through the light trapping structure. In other words, the incident light propagates annularly in the light trapping structure and the absorption structure. The annular propagation may reduce the size requirements of the light trapping structure and the absorption structure, that is, the annular propagation may reduce the size requirements of the photodetector, and a smaller size of the photodetector may bring smaller parasitic parameters of the photodetector, thereby enabling the photodetector to have a higher bandwidth. Therefore, the photodetector provided by the embodiments of the disclosure may balance a high bandwidth and a high responsivity simultaneously.

The above are only specific implementations of the disclosure, but the scope of protection of the disclosure is not limited thereto. Any variations or replacements apparent to those skilled in the art within the technical scope disclosed by the disclosure shall fall within the scope of protection of the disclosure. Therefore, the scope of protection of the disclosure shall be subject to the scope of protection of the claims.

### INDUSTRIAL APPLICABILITY

With the photodetector provided by the embodiments of the disclosure, the incident light enters the light trapping structure through the waveguide structure along the direction tangent to the second side on which the second sidewall of the light trapping structure is positioned, and the incident light is absorbed by coupling the incident light to the absorption structure through the light trapping structure. Furthermore, the light trapping structure and the absorption structure adopt structures such as circular, optimally deformed circular-like or polygonal structures, which may confine light to stably travelling within an enclosed structure and reduce the excitation to high-order modes of the incident light during the propagation process in the light trapping structure and the absorption structure. In this way, the leakage of light may be reduced, and thereby the responsivity of the photodetector is improved. In addition, in the light trapping structure, the incident light can not escape from the light trapping structure in the first direction due to the total internal reflection effect of the sidewalls, and finally all of the incident light is coupled into the absorption structure along the second direction. In the absorption structure, the incident light will also be confined within the absorption structure due to the total internal reflection effect of the sidewalls. In other words, the incident light propagates annularly in the light trapping structure and the absorption structure until the incident light is completely absorbed. The annular propagation may reduce the size requirements of the light trapping structure and the absorption structure, that is, the annular propagation may reduce the size requirements of the photodetector, and a smaller size of the photodetector may bring smaller parasitic parameters of the photodetector, thereby enabling the photodetector to have a higher bandwidth. Therefore, the photodetector provided by the embodiments of the disclosure may balance a high bandwidth and a high responsivity simultaneously.

1. A photodetector, comprising a waveguide structure, a light trapping structure and an absorption structure, wherein
the waveguide structure extends into the light trapping structure; a first side, on which a first sidewall of the waveguide structure is positioned, is tangent to a second side, on which a second sidewall of the light trapping structure is positioned; and the waveguide structure is configured to import incident light into the light trapping structure in a direction tangent to the first side;
the imported light is confined to travel annularly within the light trapping structure by total internal reflection of sidewalls of the light trapping structure, and the imported light is coupled into the absorption structure through the light trapping structure; and
the absorption structure is positioned on the light trapping structure; the coupled light is confined to travel annularly within the absorption structure by total internal reflection of sidewalls of the absorption structure, and the coupled light is converted into electrons and holes.

2. The photodetector of claim 1, wherein a shape of a projection of the waveguide structure on a preset plane comprises an elongated shape;
a shape of a projection of the light trapping structure on the preset plane comprises an enclosed shape formed by at least one straight line and/or at least one curve; and an angle formed by the second side, on which the second sidewall of the light trapping structure is positioned, and a third side, on which a third sidewall of the light trapping structure is positioned, is an obtuse angle; and
the preset plane is perpendicular to a direction of a thickness of the light trapping structure, and the third sidewall is a sidewall where the incident light is reflected for a first time after the incident light enters the light trapping structure.

3. The photodetector of claim 2, wherein the shape of the projection of the light trapping structure on the preset plane comprises one of:
a circle;
an enclosed shape formed by connecting a plurality of curves;
an enclosed shape formed by connecting a plurality of straight lines and a plurality of curves; or
a polygon.

4. The photodetector of claim 3, wherein the polygon comprises a regular polygon and has a number of sides greater than or equal to 6.

5. The photodetector of claim 2, wherein the projection of the light trapping structure on the preset plane covers a projection of the absorption structure on the preset plane.

6. The photodetector of claim 1, further comprising a slab structure, a first doped structure, a first doped region, a second doped region, a first electrode and a second electrode, wherein
the slab structure surrounds the waveguide structure and the light trapping structure;
and a thickness of the waveguide structure is greater than a thickness of the slab structure;
the first doped structure is positioned in the slab structure and surrounds the light trapping structure;
the first doped region is positioned on a surface of the first doped structure and a region with a certain depth downward from the surface of the first doped structure;
the second doped region is positioned on a surface of the absorption structure and a region with a certain depth downward from the surface of the absorption structure;
the first electrode is positioned on the first doped region, and the first electrode is configured to collect electrons or holes flowing sequentially along the absorption structure, the light trapping structure, the first doped structure, and the first doped region; and
the second electrode is positioned on the second doped region, and the second electrode is configured to collect electrons or holes flowing sequentially along the absorption structure and the second doped region.

7. The photodetector of claim 6, wherein the thickness of the waveguide structure is the same as a thickness of the light trapping structure, and the thickness of the waveguide structure is greater than the thickness of the slab structure.

8. The photodetector of claim 6, further comprising a second doped structure and a recessed structure, wherein
the second doped structure is positioned between the slab structure and the light trapping structure; a thickness of the second doped structure is less than a thickness of the light trapping structure, the thickness of the second doped structure is less than a thickness of the first doped structure; and the thickness of the waveguide structure is the same as the thickness of the light trapping structure;
the recessed structure is positioned between the slab structure and the waveguide structure; a thickness of the recessed structure is less than the thickness of the slab structure, and the thickness of the recessed structure is less than the thickness of the waveguide structure; and
the first electrode is further configured to collect electrons or holes flowing sequentially along the absorption structure, the light trapping structure, the second doped structure, the first doped structure, and the first doped region.

9. The photodetector of claim 8, wherein a doping concentration of the first doped structure is greater than or equal to a doping concentration of the second doped structure; and the doping concentration of the second doped structure is greater than or equal to a doping concentration of the light trapping structure.
